(19) United States
(12) Patent Application Publication
(10) Pub. No.: US 2025/0279756 A1
(43) Pub. Date: Sep. 4, 2025

(54) SYSTEMS AND METHODS FOR A CONTINUOUS TIME DC BLOCKING TRANSIMPEDANCE AMPLIFIER CIRCUIT

(71) Applicant: QUALCOMM Incorporated, San Diego, CA (US)

(72) Inventors: Ramkumar SIVAKUMAR, San Diego, CA (US); Htet NAING, San Diego, CA (US); Dongyang TANG, San Diego, CA (US); William Wei-Ting KUO, San Diego, CA (US); Sherif GALAL, Irvine, CA (US)

(21) Appl. No.: 18/593,695

(22) Filed: Mar. 1, 2024

(51) Int. Cl. H03F 3/45

(52) U.S. Cl. CPC H03F 3/45475; H03F 2200/129

(57) ABSTRACT

An example of an apparatus includes a transimpedance amplifier (TIA) and an integrator circuit that includes an operational amplifier, a capacitor coupled between the operational amplifier's inverting input and output, a first FET coupled between the inverting input of the op amp and the output of the TIA, a resistive element connected to a lower supply rail, and a second FET coupled between the inverting input of the TIA and the resistive element and having a second gate connected to the output of the operational amp.

### FIELD

Aspects of the present disclosure relate generally to integrated circuits, transimpedance amplifiers, integrators, and in particular to circuits for measuring a low frequency AC component of a signal that has a large DC bias.

### BACKGROUND OF THE INVENTION

Sensor signals such as photo plethysmography (PPG) sensor signals have an AC component that may be used for pulse rate measurements and a DC component that may be used for other measurements such as peripheral oxygen saturation (SpO2) measurements. The ratio of the AC component to the DC component of a PPG signal can be in the range of 0.02% to 2%. The frequency of the AC component can be on the order of 1 Hz. As such, a filter that can filter the AC component from the DC component may require a discrete resistor or discrete capacitor or both.

### SUMMARY OF THE INVENTION

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to an apparatus. The apparatus can include: a transimpedance amplifier (TIA) (e.g., FIG. 1 110) including a TIA inverting input (e.g., FIG. 1 112), a TIA noninverting input (e.g., FIG. 1 114), and a TIA output (e.g., FIG. 1 116); an integrator circuit (e.g., FIG. 1 120) comprising: an operational amplifier (e.g., FIG. 1 124) including an op amp inverting input (e.g., FIG. 4 418), an op amp noninverting input (e.g., FIG. 4 416), and an op amp output (e.g., FIG. 4 420); a capacitor (e.g., FIG. 1 123) coupled between the op amp inverting input of the operational amplifier and the op amp output of the operational amplifier; a first field effect transistor (FET) (e.g., FIG. 2 202) coupled between the op amp inverting input of the operational amplifier and the TIA output of the TIA; a first resistive element (e.g., FIG. 1 128), a first side of the first resistive element connected to a lower supply rail (e.g., FIG. 1 133); and a second FET (e.g., FIG. 1 126) coupled between a second side of first resistive element and the TIA inverting input of the TIA, the second FET having a second gate connected to the op amp output of the operational amplifier.

Another aspect of the disclosure relates to a method. The method can include: receiving a signal at an inverting input of a transimpedance amplifier (TIA), the signal including an AC component and a DC component; and passing an output signal of the TIA to an integrator circuit configured to cancel the DC component of the signal, the integrator circuit comprising: an operational amplifier including an op amp inverting input, an op amp noninverting input, and an op amp output; a capacitor coupled between the op amp inverting input of the operational amplifier and the op amp output of the operational amplifier; a first field effect transistor (FET) coupled between the op amp inverting input of the operational amplifier and a TIA output of the TIA; a first resistive element, a first side of the first resistive element connected to a lower supply rail; and a second FET coupled between a second side of first resistive element and the TIA inverting input of the TIA, the second FET having a second gate connected to the op amp output of the operational amplifier.

Another aspect of the disclosure relates to an apparatus. The apparatus can include: an input means for receiving an input current that includes a first component and a second component; an integrator means for subtracting the second component from the input current; a transimpedance means for converting the first component to a voltage; a resistive means for switching between a high resistance state and a low resistance state, wherein: the integrator means includes the resistive means; an output of the transimpedance means is connected to the resistive means; the input means and the output of the integrator means are connected to an input of the transimpedance means; and the integrator means and the transimpedance means are implemented by an integrated circuit.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1 illustrates a circuit diagram of an example of an integrated circuit configured to measure the AC component and the DC component of a signal, in accordance with an aspect of the disclosure.

FIG. 2 illustrates a circuit diagram of an example of a switched floating bulk device, in accordance with another aspect of the disclosure.

FIG. 3 illustrates a circuit diagram of an example of a transimpedance amplifier, in accordance with another aspect of the disclosure.

FIG. 4 illustrates a circuit diagram of an example of rest phase maintenance circuit, in accordance with another aspect of the disclosure.

FIG. 5 illustrates a circuit diagram of an example of C2 switch circuit in a transimpedance amplifier (TIA), in accordance with another aspect of the disclosure.

FIG. 6 illustrates a circuit diagram of an example of DC output circuit, in accordance with another aspect of the disclosure.

FIG. 7 illustrates an example of an operational phases table, in accordance with another aspect of the disclosure.

FIG. 8 illustrates a flow diagram of an example method for a continuous time DC blocking transimpedance circuit to convert the AC component of an input signal to an AC voltage signal in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

Sensor signals such as photo plethysmography (PPG) sensor signals have an AC component that may be used for pulse rate measurements and a DC component that may be used for other measurements such as peripheral oxygen saturation (SpO2) measurements. The ratio of the AC component to the DC component of a PPG signal can be in the range of 0.02% to 2%. As such, a fine resolution analog to digital converter (ADC) may be required for digitizing the signal such that the AC component of the digitized signal can be isolated. However, fine resolution ADCs require substantial area on an integrated circuit chip. An option is to cancel the DC component of the signal in the analog domain such that the ADC measures the AC component without also measuring the DC component. An integrator circuit may be used to cancel the DC component. However, the integrator circuit can include a filtering aspect that should have a cutoff frequency near the frequency of the AC signal. The filtering aspect may include a resistor and a capacitor and have a cutoff frequency that is a function of resistor's resistance multiplied by the capacitor's capacitance. The frequency of the AC component can be on the order of 1 Hz when a heartbeat is being measured. It may be difficult to implement the required resistor in an integrated circuit and the required capacitor can require substantial area on an integrated circuit chip. As a result, the resistor and the capacitor may be located off chip, thereby increasing bills of material and increasing the size of devices that measure signals such as PPG signal.

The integrator circuit's resistive element can be a floating bulk field effect transistor (FET) instead of a resistor. A FET in an integrated circuit typically has a connection between the FET's gate and the FET's bulk such that the FET's bulk does not float. Testing has shown that a floating bulk FET may have a source to drain resistance greater than 100 giga Ohms. An integrator circuit that has a floating bulk FET as a resistive element and a 25 pF integrating capacitor (Cint) may therefore be used for canceling the DC component of a signal such that an AC component on the order of 1 HZ can be measured. The circuit may operate in phases such as a DC acquisition phase and an AC measurement phase. The integrator circuit can lock onto the DC component during the DC measurement phase such that the DC component is canceled from the input to the TIA during the AC measurement phase.

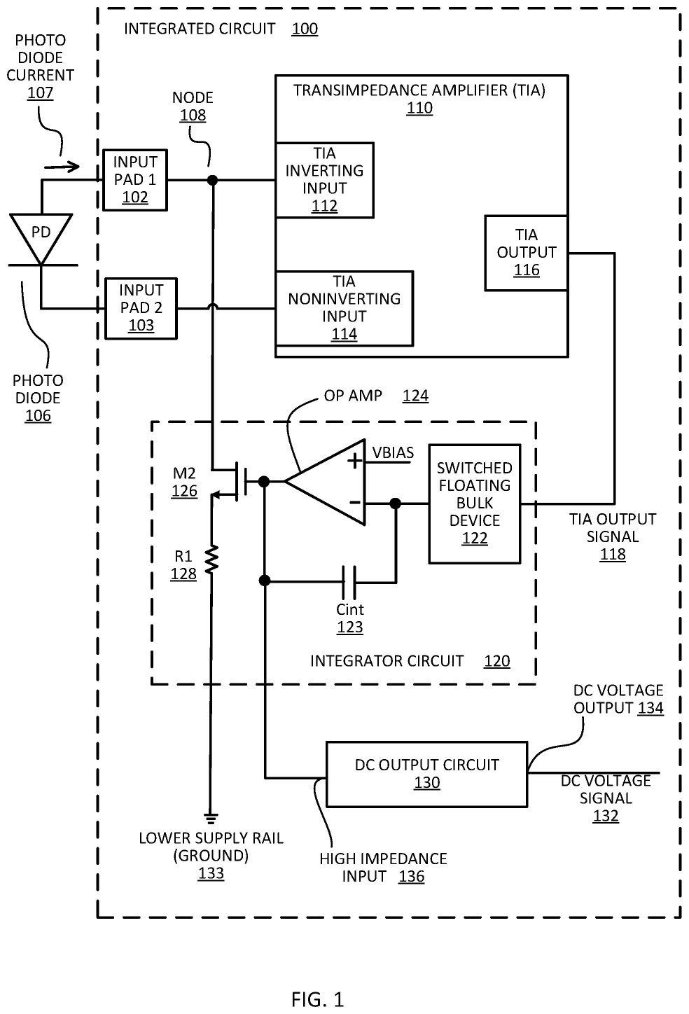

FIG. 1 illustrates a circuit diagram of an example of an integrated circuit 100 configured to measure the AC component and the DC component of a signal, in accordance with an aspect of the disclosure. The signal can be carried by a photodiode current 107 produced by a photodiode (PD) that may be connected to the input pads (e.g., first input pad 102 and second input pad 103) of the integrated circuit 100. The PD current 107 splits at node 108 into a first component and a second component. The first component enters the TIA inverting input 112 of a TIA 110 that converts the first component into a voltage that is the TIA output signal 118. The TIA inverting input 112 of the TIA 110 can be connected to the first input pad 102 and node 108. The TIA noninverting input 114 of the TIA 110 can be connected to the second input pad 103 and thereby connected to the PD 106. The TIA output 116 is connected to a switched floating bulk device 122 of the integrator circuit 120. The integrator circuit 120 includes an operational amplifier (op amp) 124. The switched floating bulk device 122 is coupled between the TIA output 116 and the op amp inverting input of the op amp. A capacitor (Cint) 123 is coupled between the op amp inverting input of the op amp 124 and the op amp output of the op amp. The switched floating bulk device 122 can be a floating bulk FET that can be switched between a high resistance state (e.g., >100 giga OHM) and a low resistance state (e.g., <1 Ohms). For example, the floating bulk FET may be an n-channel device that can be turned on and off by a resistance state control signal that is input to the gate of the floating bulk FET. The switched floating bulk device 122 can be in the high resistance state when the floating bulk FET is on and can be in the low resistance state when the floating bulk FET is off.

The output of the integrator circuit 120 is connected to the gate of a second FET (M2) 126. A resistor (R1) 128 is coupled between the drain of M2 126 and the lower supply rail 133. The lower supply rail 133 is indicated by the ground symbol. As discussed above, a first component of the PD current enters the TIA inverting input 112 of the TIA. The second component of the PD current 107 passes through M2, through R1, and then to the lower supply rail 133.

The switched floating bulk device 122 can be in the low resistance state during the DC acquisition phase. The integrator circuit has a cutoff frequency that is a function of the capacitance of Cint 123 (e.g., 25 pF) and the resistance of the switched floating bulk device 122 (e.g., <1 Ohm in the low resistance state). As such, the integrator circuit 120 stores charge on Cint 123 such that the current through R1 equals the DC component of the PD current. Furthermore, the integrator circuit converts the DC component of the PD current into a voltage at the op amp output of the op amp 124 during the DC acquisition phase and thereby acquires the DC component. The op amp output of the op amp 124 is therefore connected to the input of a DC output circuit 130 that produces a DC voltage signal 132 on the DC voltage output 134. The input to the DC output circuit 130 can be a high impedance input 136 (e.g., the gate of a FET) such that the DC output circuit 130 does not drain current from Cint 123. A PPG application, such as measuring SpO2, may use the DC voltage signal at the end of the DC acquisition phase to measure the DC component of the PD current.

The switched floating bulk device 122 can be in the high resistance state during the AC measurement phase. The integrator circuit has a cutoff frequency that is a function of the capacitance of Cint 123 (e.g., 25 pF) and the resistance of the switched floating bulk device 122 (e.g., >100 giga Ohms in the high resistance state). As such, the charge on Cint 123 is locked in place because every current path out of Cint 123 is a high impedance path when the switched floating bulk device 122 is in the high resistance state. As such, the DC component of the PD current 107 is sunk through M2 126 and R1 128. The remainder of the PD current, the AC component, passes into the TIA inverting input of the TIA 110 which converts the AC component into an AC voltage signal that is available at the TIA output 116 of the TIA 110 during the AC measurement phase.

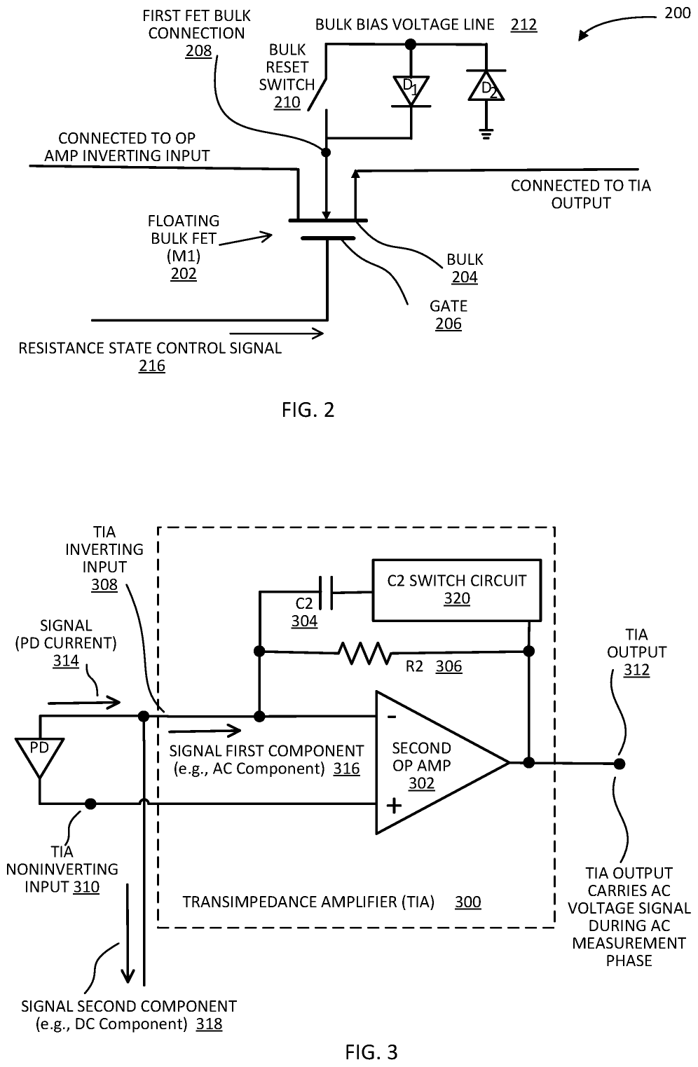

FIG. 2 illustrates a circuit diagram of an example of a switched floating bulk device 200, in accordance with another aspect of the disclosure. The switched floating bulk device 200 can include a floating bulk FET (M1) 202. In the example, M1 202 is an n-channel FET having its drain connected to the TIA output and its source connected to the op amp inverting input of the integrator circuit's operational amplifier. A resistance state control signal 216 can be input into the gate 206 of M1 202 such that the resistance state control signal 216 puts the switched floating bulk device 200 in the high resistive state (e.g., >100 giga Ohm) or in the low resistive state (e.g., <1 Ohm). The bulk 204 of M1 202 is allowed to float when a bulk reset switch 210 is open. A FET may be used as a bulk reset switch. Experimentation has shown that the source to drain resistance is insufficient for the AC acquisition phase when the bulk is not floating. However, charge can accumulate on the bulk when the bulk is allowed to float, which is why most other applications connect the bulk to the gate. The gate of the floating bulk FET 202 is not connected directly to the bulk of the floating bulk FET. Here, “directly connected” means connected by a wire, a conductive trace, a conductive via, or a line. The bulk reset switch 210 can be coupled between a bulk bias voltage line 212 and the bulk connection 208 of the first FET. The potential of the bulk can be set relative to a bulk bias voltage line 212 by closing the bulk reset switch 210. The bulk reset switch 210 should be open when the switched floating bulk device 200 is in the high resistance state (e.g., during the AC acquisition phase) because otherwise the resistance between the source and drain may be insufficient. The bulk reset switch 210 can be pulsed such that the bulk reset switch 210 closes and then opens to set the potential of the bulk relative to the voltage of the bulk bias voltage line 212.

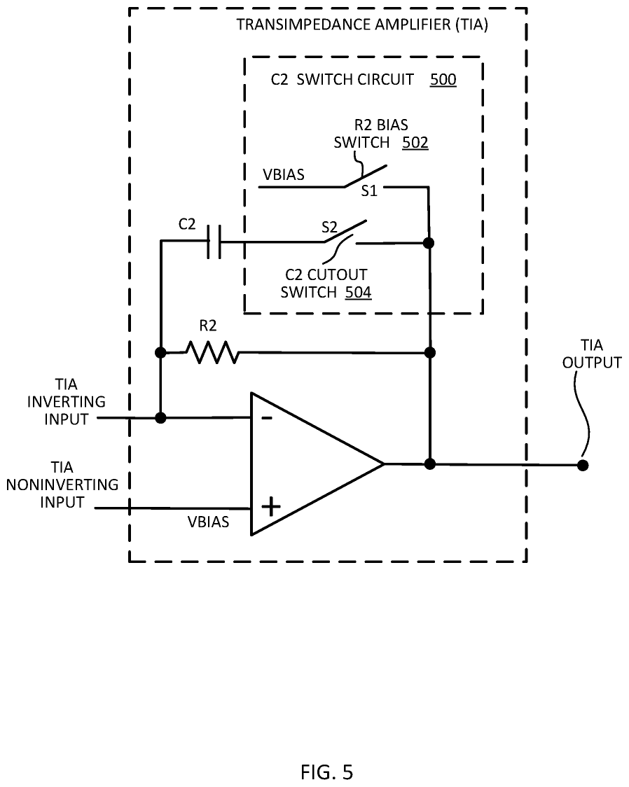

FIG. 3 illustrates a circuit diagram of an example of a transimpedance amplifier 300, in accordance with another aspect of the disclosure. The TIA includes a second op amp 302 that has a second op amp inverting input, a second op amp noninverting input, and a second op amp output. A signal 314 such as a PD current splits into a first component 316 and a second component 318. The second component may be input to the integrator circuit. The first component 316 may be input to the TIA inverting input of the TIA 300. The TIA inverting input 308 is connected to the second op amp inverting input of the second op amp 302, a second resistor 306 (R2), and a second capacitor 304 (C2). The TIA noninverting input 310 is connected to the second op amp noninverting input of the second op amp 302. R2 306 is coupled between the second op amp inverting input of the second op amp 302 and the second op amp output of the second op amp 302. The second op amp output of the second op amp 302 is the TIA output of the TIA. The TIA converts the AC component of the signal into an AC voltage signal. The TIA output 312 carries the AC voltage signal during the AC measurement phase and may therefore be connected to a DAC that produces a digital version of the AC voltage signal. A C2 switch circuit 320 is coupled between C2 304 and the second op amp output of the second op amp. FIG. 5, discussed below, illustrates an example of a C2 switch circuit.

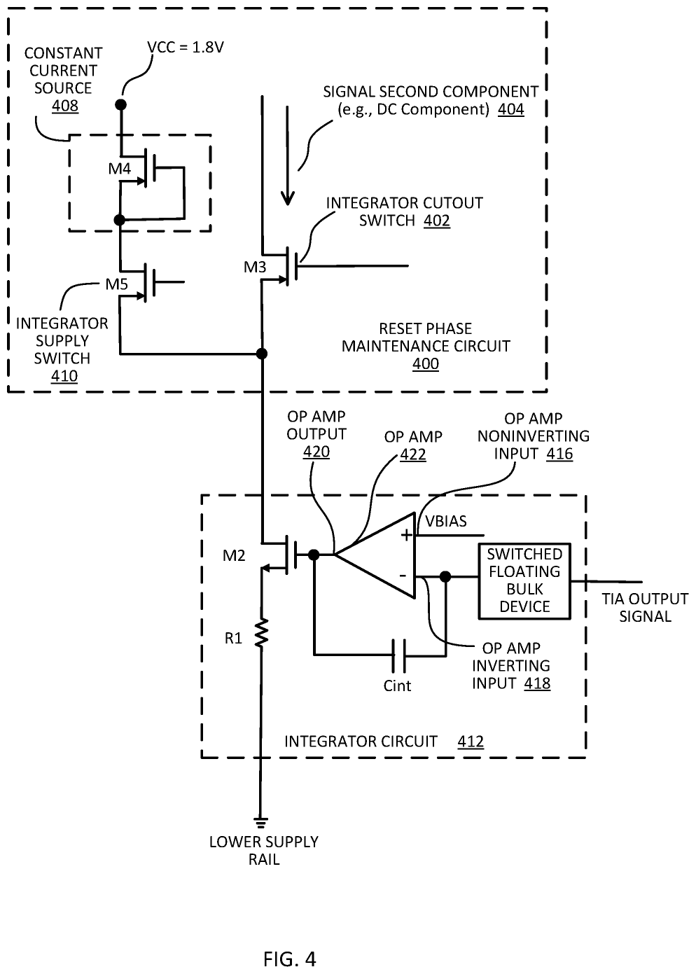

FIG. 4 illustrates a circuit diagram of an example of rest phase maintenance circuit 400, in accordance with another aspect of the disclosure. As discussed above, the circuit may operate in operational phases that include a DC acquisition phase and an AC measurement phase. A rest phase is another operational phase that may be entered to save energy. A PPG application may have a light emitting diode (LED) that illuminates tissues and a PD that produces a PD current proportional to the light reflected from the tissues and into the PD. To conserve energy, many PPG applications (e.g., smart watches) pulse the LED. The PD current may drop to near zero when the LED is off. The integrator circuit 412 can include an operational amplifier 422 that has an op amp inverting input 418, an op amp noninverting input 416, and an op amp output 420. The op amp noninverting input 416 can be connected to a bias voltage (VBIAS). The integrator circuit can be supplied with a maintenance current during the rest phase such that the integrator circuit maintains the charge stored by Cint. The maintenance current can be supplied by a constant current source 408. An integrator supply switch 410 (M5) is coupled between the constant current source 408 and the integrator circuit 412. The integrator supply switch 410 can be closed during the rest phase such that the integrator circuit 412 receives the maintenance current. An integrator cutout switch 402 (M3) can be coupled between the inverting input of the TIA and the integrator circuit to thereby prevent the maintenance current from entering the PD or the TIA or from acting as a simulacrum of the PD current. The integrator supply switch 410 (M5) can be open and the integrator cutout switch 402 (M3) can be closed during the DC acquisition phase and during the AC measurement phase such that the second signal component 404 is received by the integrator circuit 412 and the maintenance current is not received by the integrator circuit 412 during those operational phases.

FIG. 5 illustrates a circuit diagram of an example of a C2 switch circuit 500 in a transimpedance amplifier (TIA), in accordance with another aspect of the disclosure. The C2 switch circuit 500 can include a R2 bias switch 502 (S1) and a C2 cutout switch 504 (S2). The switches may be implemented by FETs. The TIA includes the C2 switch circuit 500, the second op amp (e.g., FIG. 3 302), a second capacitor (C2), and a second resistor (R2). R2 is coupled between the second op amp inverting input and the second op amp output of the second op amp. One side of C2 is coupled between the second op amp inverting input of the second op amp and the C2 cutout switch 504 (S2). The C2 cutout switch 504 (S2) is coupled between C2 and the second op amp output of the second op amp.

Closing the C2 cutout switch 504 (S2) electrically connects C2 in parallel with R2 and opening S2 disconnects C2 from one side of R2 and from the second op amp output of the second op amp. Closing S1 connects the second op amp output of the second op amp and one side of R2 to a bias voltage (VBIAS). S2 can be closed and S1 can be open during the DC acquisition phase and during the AC measurement phase such that C2 is electrically connected in parallel with R2 and the TIA operates as a TIA. S2 can be open and S1 can be closed during the rest phase, effectively quiescing the circuit. S1 and S2 may be implemented by FETs.

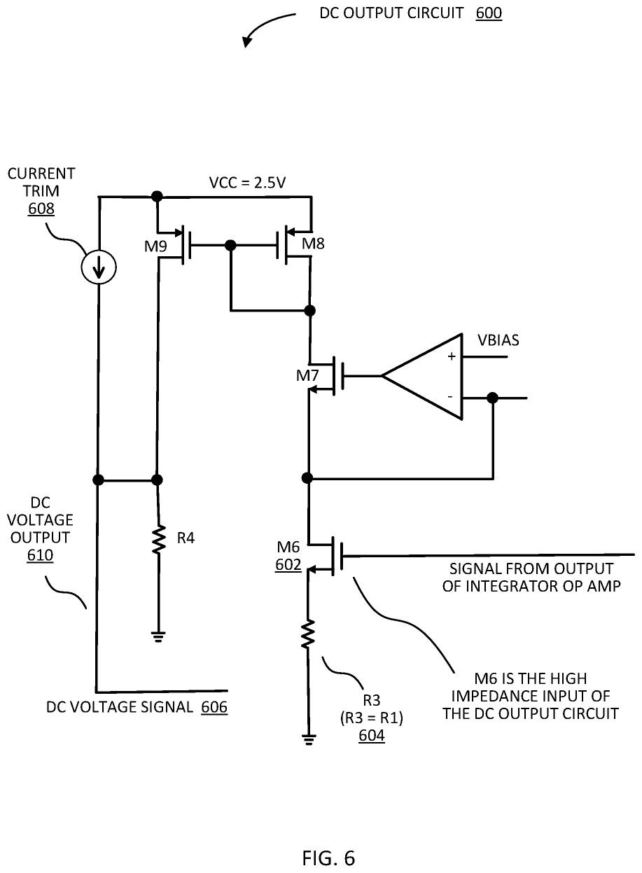

FIG. 6 illustrates a circuit diagram of an example of a DC output circuit 600, in accordance with another aspect of the disclosure. This example of a DC output circuit uses a current mirror similar to those known in the art. Referring to FIG. 1, the op amp output of the op amp in the integrator circuit is connected to the gate of M2 126 and to the input of a DC output circuit. FIG. 5 illustrates an example in which the gate of M6 602, an n-channel FET, is a high impedance input to the DC output circuit 600. As such, the op amp output of the op amp in the integrator circuit is connected to the gate of M6 602, thereby setting the current through R3 604. The current through R3 may equal the current through R1 when R3=R1. The current through R1 can be the DC component of the PD current. The current mirror circuit therefore sends a current equaling the DC component of the PD current through R4. The voltage across R4 is the DC voltage signal 606 that may be used, for example, to measure SpO2 in a PPG application. The DC voltage output 610 is indicated as the line on which the DC output circuit produces the DC voltage signal. The DC output circuit 600 may include a current trim 608 that can be used for calibration or for adjusting the current through R4. The DC output circuit 600 is an example of a circuit that can be implemented efficiently within an integrated circuit.

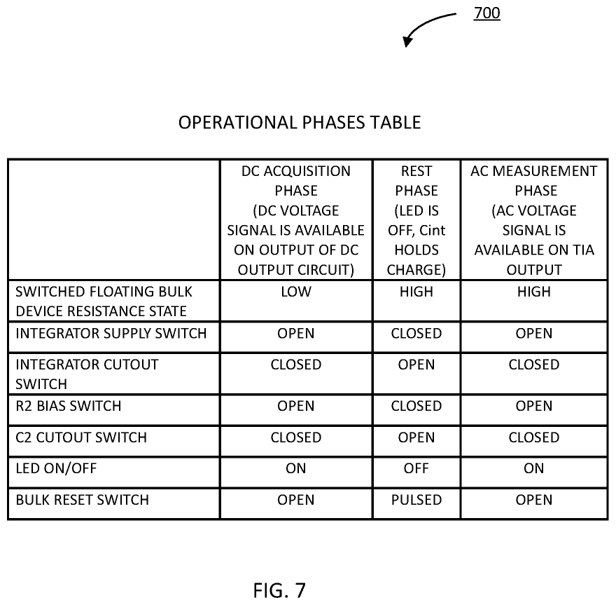

FIG. 7 illustrates an example of an operational phases table 700, in accordance with another aspect of the disclosure. The operational phases can include a DC acquisition phase, a rest phase, and an AC measurement phase. In an example, the sequence of phases can repeat the series: DC acquisition phase-rest phase-AC measurement phase-rest phase. During the DC acquisition phase, the switched floating bulk device (e.g., FIG. 2 200) can be in the low resistance state, the integrator supply switch (e.g., FIG. 4 410) can be open, the integrator cutout switch (e.g., FIG. 4 402) can be closed, the R2 bias switch (e.g., FIG. 5 502) can be open, the C2 cutout switch (e.g., FIG. 5 504) can be closed, and the bulk reset switch (e.g., FIG. 2 210) can be open. During the rest phase, the switched floating bulk device (e.g., FIG. 2 200) can be in the high resistance state, the integrator supply switch (e.g., FIG. 4 410) can be closed, the integrator cutout switch (e.g., FIG. 4 402) can be open, the R2 bias switch (e.g., FIG. 5 502) can be closed, the C2 cutout switch (e.g., FIG. 5 504) can be open, and the bulk reset switch (e.g., FIG. 2 210) can be pulsed. The bulk reset switch can be pulsed by briefly closing it and then opening it during the rest phase. During the AC measurement phase, the switched floating bulk device (e.g., FIG. 2 200) can be in the high resistance state, the integrator supply switch (e.g., FIG. 4 410) can be open, the integrator cutout switch (e.g., FIG. 4 402) can be closed, the R2 bias switch (e.g., FIG. 5 502) can be open, the C2 cutout switch (e.g., FIG. 5 504) can be closed, and the bulk reset switch (e.g., FIG. 2 210) can be open.

A PPG application may use a LED to illuminate tissue. The light from the LED can be reflected from tissue into a photodiode (e.g., FIG. 1 106) that produces a photodiode current (e.g., FIG. 1 107). The OD current can be a signal that is processed to obtain the AC voltage signal (for pulse measurement) and the DC voltage signal (for SpO2 measurement). In such an application, the LED may be on during the DC acquisition and AC measurement phases but may be off during the rest phase.

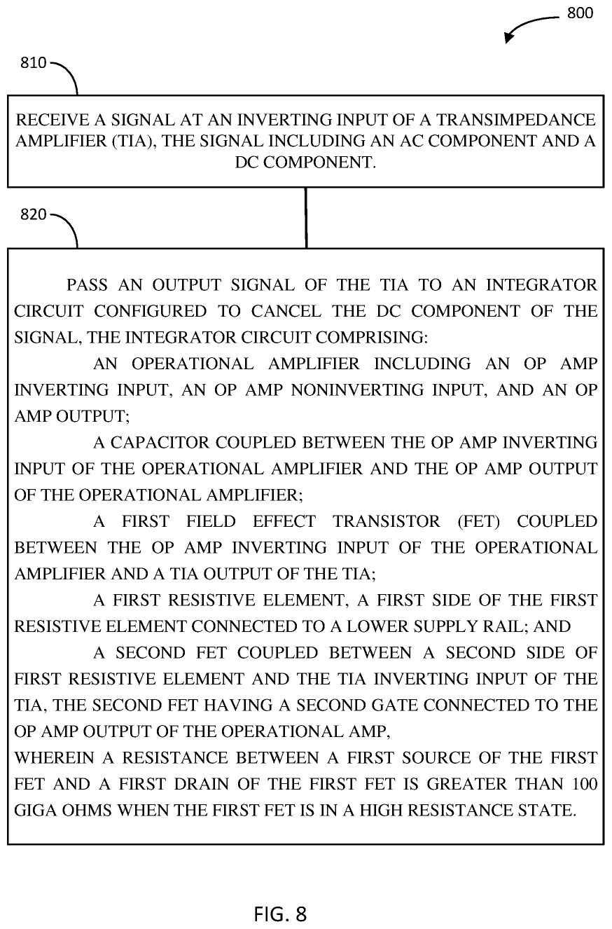

FIG. 8 illustrates a flow diagram of an example method 800 for a continuous time DC blocking transimpedance circuit to convert the AC component of an input signal to an AC voltage signal in accordance with another aspect of the disclosure. At block 810, a signal can be received at an inverting input of a transimpedance amplifier (TIA), the signal including an AC component and a DC component. At block 820, an output signal of the TIA can be passed to an integrator circuit configured to cancel the dc component of the signal, the integrator circuit comprising: an operational amplifier including an op amp inverting input, an op amp noninverting input, and an op amp output; a capacitor coupled between the op amp inverting input of the operational amplifier and the op amp output of the operational amplifier; a first field effect transistor (FET) coupled between the op amp inverting input of the operational amplifier and a TIA output of the TIA; a first resistive element, a first side of the first resistive element connected to a lower supply rail; and a second FET coupled between a second side of first resistive element and the TIA inverting input of the TIA, the second FET having a second gate connected to the op amp output of the operational amp, wherein a resistance between a first source of the first FET and a first drain of the first FET is greater than 100 giga ohms when the first FET is in a high resistance state.

The examples disclosed herein may be implemented by an integrated circuit when the sizes of the components are selected such that an integrated circuit can implement the examples in an efficient and cost-effective manner. For example: Cint can be 25 pF; R1, R2, and R3 can be 1 Mohm, and C2 can be 1.4 pF. In such an example, VBIAS can be 1 V, Vcc for the op amps can be 1.8 V, and Vcc for the DC output circuit can be 2.5 V.

The following provides an overview of aspects of the present disclosure:

Aspect 1: An apparatus comprising: a transimpedance amplifier (TIA) including a TIA inverting input, a TIA noninverting input, and a TIA output; an integrator circuit comprising: an operational amplifier including an op amp inverting input, an op amp noninverting input, and an op amp output; a capacitor coupled between the op amp inverting input of the operational amplifier and the op amp output of the operational amplifier; a first field effect transistor (FET) coupled between the op amp inverting input of the operational amplifier and the TIA output of the TIA; a first resistive element, a first side of the first resistive element connected to a lower supply rail; and a second FET coupled between a second side of first resistive element and the TIA inverting input of the TIA, the second FET having a second gate connected to the op amp output of the operational amplifier.

Aspect 2: The apparatus of aspect 1, wherein the first FET is configured to switch between a high resistance state and a low resistance state; a resistance between a first source of the first FET and a first drain of the first FET is greater than 100 giga Ohms when the first FET is in the high resistance state; and the integrator circuit is configured to cancel a DC component of a signal that is input to a node connected to the TIA inverting input of the TIA.

Aspect 3: The apparatus of aspects 1-2, wherein the signal has an AC component and the DC component; the TIA is configured to convert the AC component into an AC voltage signal on the TIA output of the TIA when the first FET is in the high resistance state; the integrator circuit is configured to cancel the DC component of the signal when the first FET is in the high resistance state; and the integrator circuit is configured to acquire the DC component when the first FET is in the low resistance state.

Aspect 4: The apparatus of aspects 1-3, further including a DC output circuit including a high impedance input connected to the op amp output of the operational amplifier, and a DC voltage output that produces a DC voltage signal that is proportional to the DC component of the signal.

Aspect 5: The apparatus of aspect 4, wherein the TIA, the integrator circuit, and the DC output circuit are implemented by an integrated circuit.

Aspect 6: The apparatus of aspects 1-3, further including: an integrator cutout switch coupled between the TIA inverting input of the TIA and the second FET; and an integrator supply switch coupled between a current source and a second source of the second FET.

Aspect 7: The apparatus of aspect 6, wherein: the apparatus is configured to operate in a plurality of phases that include a DC acquisition phase, a rest phase, and an AC measurement phase, during the DC acquisition phase, the first FET is in the low resistance state, the integrator cutout switch is closed, the integrator supply switch is open, and of the integrator circuit acquires the DC component of the signal; during the rest phase, the first FET is in the high resistance state, the integrator cutout switch is open, and the integrator supply switch is closed; and during the AC measurement phase, the first FET is in the high resistance state, the integrator cutout switch is closed, the integrator supply switch is open, and the TIA converts the AC component of the signal into the AC voltage signal.

Aspect 8: The apparatus of aspect 7, further comprising a bulk reset switch coupled between a bulk of the first FET and a bulk bias voltage line, wherein the bulk reset switch is open during the DC acquisition phase and the AC measurement phase.

Aspect 9: The apparatus of aspects 1-8, wherein the bulk reset switch closes and then opens during the rest phase.

Aspect 10: The apparatus of aspects 2-10, further including a DC output circuit including a high impedance input connected to the op amp output of the operational amplifier, and a DC voltage output that produces a DC voltage signal that is proportional to the DC component of the signal.

Aspect 11: The apparatus of aspects 1-9, wherein a bulk of the first FET is not directly connected to a first gate of the first FET.

Aspect 12: A method comprising: receiving a signal at an inverting input of a transimpedance amplifier (TIA), the signal including an AC component and a DC component; and passing an output signal of the TIA to an integrator circuit configured to cancel the DC component of the signal, the integrator circuit comprising: an operational amplifier including an op amp inverting input, an op amp noninverting input, and an op amp output; a capacitor coupled between the op amp inverting input of the operational amplifier and the op amp output of the operational amplifier; a first field effect transistor (FET) coupled between the op amp inverting input of the operational amplifier and a TIA output of the TIA; a first resistive element, a first side of the first resistive element connected to a lower supply rail; and a second FET coupled between a second side of first resistive element and the TIA inverting input of the TIA, the second FET having a second gate connected to the op amp output of the operational amplifier.

Aspect 13: The method of aspect 12, further including: controlling the first FET to put the first FET into a high resistance state or into a low resistance state, wherein: a resistance between a first source of the first FET and a first drain of the first FET is greater than 100 giga Ohms when the first FET is in the high resistance state; the TIA is configured to convert the AC component into an AC voltage signal on the TIA output of the TIA when the first FET is in the high resistance state; the integrator circuit is configured to cancel the DC component of the signal when the first FET is in the high resistance state; and the integrator circuit is configured to acquire the DC component when the first FET is in the low resistance state.

Aspect 14: The method of aspect 13, further including producing a DC voltage signal that is proportional to the DC component of the signal at a DC voltage output of a DC output circuit that includes a high impedance input connected to the op amp output of the operational amplifier.

Aspect 15: The method of aspect 14, wherein the TIA, the integrator circuit, and the DC output circuit are implemented by an integrated circuit.

Aspect 16: The method of aspect 13, wherein: an integrator cutout switch is coupled between the TIA inverting input of the TIA and the second FET; and an integrator supply switch is coupled between a constant current source and the second FET.

Aspect 17: The method of aspect 12-16, wherein: the first FET is a floating bulk device when a bulk reset switch is open; and a bulk of the first FET is coupled to a bulk bias voltage line when the bulk reset switch is closed.

Aspect 18: An apparatus, comprising: an input means for receiving an input current that includes a first component and a second component; an integrator means for subtracting the second component from the input current; a transimpedance means for converting the first component to a voltage; a resistive means for switching between a high resistance state and a low resistance state, wherein: the integrator means includes the resistive means; an output of the transimpedance means is connected to the resistive means; the input means and the output of the integrator means are connected to an input of the transimpedance means; and the integrator means and the transimpedance means are implemented by an integrated circuit.

Aspect 19: The apparatus of aspect 18, wherein: the resistive means is a floating bulk device when a bulk reset switch is open; and a bulk of the resistive means is coupled to a bulk bias voltage line when the bulk reset switch is closed.

Aspect 20: The apparatus of aspect 18-19, wherein a resistance of the resistive means is greater than 100 giga Ohms when the resistive means is in the high resistance state.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. An apparatus comprising:
a transimpedance amplifier (TIA) including a TIA inverting input, a TIA noninverting input, and a TIA output;
an integrator circuit comprising:
an operational amplifier including an op amp inverting input, an op amp noninverting input, and an op amp output;
a capacitor coupled between the op amp inverting input of the operational amplifier and the op amp output of the operational amplifier;
a first field effect transistor (FET) coupled between the op amp inverting input of the operational amplifier and the TIA output of the TIA;
a first resistive element, a first side of the first resistive element connected to a lower supply rail; and
a second FET coupled between a second side of first resistive element and the TIA inverting input of the TIA, the second FET having a second gate connected to the op amp output of the operational amplifier.

2. The apparatus of claim 1, wherein:
the first FET is configured to switch between a high resistance state and a low resistance state;
a resistance between a first source of the first FET and a first drain of the first FET is greater than 100 giga Ohms when the first FET is in the high resistance state; and
the integrator circuit is configured to cancel a DC component of a signal that is input to a node connected to the TIA inverting input of the TIA.

3. The apparatus of claim 2, wherein:
the signal has an AC component and the DC component;
the TIA is configured to convert the AC component into an AC voltage signal on the TIA output of the TIA when the first FET is in the high resistance state;
the integrator circuit is configured to cancel the DC component of the signal when the first FET is in the high resistance state; and
the integrator circuit is configured to acquire the DC component when the first FET is in the low resistance state.

4. The apparatus of claim 3, further including a DC output circuit including a high impedance input connected to the op amp output of the operational amplifier, and a DC voltage output that produces a DC voltage signal that is proportional to the DC component of the signal.

5. The apparatus of claim 4, wherein the TIA, the integrator circuit, and the DC output circuit are implemented by an integrated circuit.

6. The apparatus of claim 3, further including:
an integrator cutout switch coupled between the TIA inverting input of the TIA and the second FET; and
an integrator supply switch coupled between a current source and a second source of the second FET.

7. The apparatus of claim 6, wherein:
the apparatus is configured to operate in a plurality of phases that include a DC acquisition phase, a rest phase, and an AC measurement phase,
during the DC acquisition phase, the first FET is in the low resistance state, the integrator cutout switch is closed, the integrator supply switch is open, and of the integrator circuit acquires the DC component of the signal;
during the rest phase, the first FET is in the high resistance state, the integrator cutout switch is open, and the integrator supply switch is closed; and
during the AC measurement phase, the first FET is in the high resistance state, the integrator cutout switch is closed, the integrator supply switch is open, and the TIA converts the AC component of the signal into the AC voltage signal.

8. The apparatus of claim 7, further comprising a bulk reset switch coupled between a bulk of the first FET and a bulk bias voltage line, wherein the bulk reset switch is open during the DC acquisition phase and the AC measurement phase.

9. The apparatus of claim 8, wherein the bulk reset switch closes and then opens during the rest phase.

10. The apparatus of claim 2, further including a DC output circuit including a high impedance input connected to the op amp output of the operational amplifier, and a DC voltage output that produces a DC voltage signal that is proportional to the DC component of the signal.

11. The apparatus of claim 1, wherein a bulk of the first FET is not directly connected to a first gate of the first FET.

12. A method comprising:
receiving a signal at an inverting input of a transimpedance amplifier (TIA), the signal including an AC component and a DC component; and
passing an output signal of the TIA to an integrator circuit configured to cancel the DC component of the signal, the integrator circuit comprising:
an operational amplifier including an op amp inverting input, an op amp noninverting input, and an op amp output;
a capacitor coupled between the op amp inverting input of the operational amplifier and the op amp output of the operational amplifier;
a first field effect transistor (FET) coupled between the op amp inverting input of the operational amplifier and a TIA output of the TIA;
a first resistive element, a first side of the first resistive element connected to a lower supply rail; and
a second FET coupled between a second side of first resistive element and the TIA inverting input of the TIA, the second FET having a second gate connected to the op amp output of the operational amplifier.

13. The method of claim 12, further including:
controlling the first FET to put the first FET into a high resistance state or into a low resistance state,
wherein:
a resistance between a first source of the first FET and a first drain of the first FET is greater than 100 giga Ohms when the first FET is in the high resistance state;
the TIA is configured to convert the AC component into an AC voltage signal on the TIA output of the TIA when the first FET is in the high resistance state;
the integrator circuit is configured to cancel the DC component of the signal when the first FET is in the high resistance state; and
the integrator circuit is configured to acquire the DC component when the first FET is in the low resistance state.

14. The method of claim 13, further including producing a DC voltage signal that is proportional to the DC component of the signal at a DC voltage output of a DC output circuit that includes a high impedance input connected to the op amp output of the operational amplifier.

15. The method of claim 14, wherein the TIA, the integrator circuit, and the DC output circuit are implemented by an integrated circuit.

16. The method of claim 13, wherein:
an integrator cutout switch is coupled between the TIA inverting input of the TIA and the second FET; and
an integrator supply switch is coupled between a constant current source and the second FET.

17. The method of claim 12, wherein:
the first FET is a floating bulk device when a bulk reset switch is open; and
a bulk of the first FET is coupled to a bulk bias voltage line when the bulk reset switch is closed.

18. An apparatus comprising:
an input means for receiving an input current that includes a first component and a second component;
an integrator means for subtracting the second component from the input current;
a transimpedance means for converting the first component to a voltage;
a resistive means for switching between a high resistance state and a low resistance state,
wherein:
the integrator means includes the resistive means;
an output of the transimpedance means is connected to the resistive means;
the input means and the output of the integrator means are connected to an input of the transimpedance means; and
the integrator means and the transimpedance means are implemented by an integrated circuit.

19. The apparatus of claim 18, wherein:
the resistive means is a floating bulk device when a bulk reset switch is open; and
a bulk of the resistive means is coupled to a bulk bias voltage line when the bulk reset switch is closed.

20. The apparatus of claim 18, wherein a resistance of the resistive means is greater than 100 giga Ohms when the resistive means is in the high resistance state.
